(19) United States
(12) Patent Application Publication
(10) Pub. No.: US 2023/0238465 A1
(43) Pub. Date: Jul. 27, 2023

(54) Enhanced Infrared Photodiodes Based on PbS/PbClx Core/Shell Nanocrystals

(71) Applicant: The Government of the United States of America, as represented by the Secretary of the Navy, Arlington, VA (US)

(72) Inventors: Adam E. Colbert, Alexandria, VA (US); Diogenes Placencia, Alexandria, VA (US); Janice E. Boercker, Fairfax, VA (US); Edward H. Aifer, Arlington, VA (US); Joseph G. Tischler, Alexandria, VA (US); Erin L. Ratcliff, Tucson, AZ (US)

(73) Assignee: The Government of the United States of America, as represented by the Secretary of the Navy, Arlington, VA (US)

(21) Appl. No.: 18/060,676

(22) Filed: Dec. 1, 2022

Related U.S. Application Data
(63) Continuation-in-part of application No. 17/375,050, filed on Jul. 14, 2021, now abandoned.
(60) Provisional application No. 63/052,988, filed on Jul. 17, 2020.

(51) Int. Cl. H01L 31/032; H01G 9/20

(52) U.S. Cl. CPC H01L 31/0324; H01G 9/2031; H10K 30/35; H10K 85/30

(57) ABSTRACT

Photodiodes configured to convert incident photons in the short-wave infrared (SWIR) to electric current, where the photodiodes have a PbS/PbClₓ core/shell nanocrystal absorber layer. The PbClₓ shell in the PbS/PbClₓ nanocrystals provide native passivation in the (100) crystal facets and enable removal of pre-device processing ligands and ligand exchange on the (111) crystal facets of the PbS/PbClₓ nanocrystals such that the photodiode exhibits reduced current densities under reverse bias and greater infrared photoresponse, providing improved device performance as compared to photodiodes having absorber layers formed from PbS core nanocrystals alone.

### CROSS-REFERENCE

This Application is a Continuation-in-Part of and claims the benefit of priority under 35 U.S.C. § 120 based on U.S. Pat. Application No. 17/375,050 filed on Jul. 14, 2021, which is a Nonprovisional of and claims the benefit of priority under 35 U.S.C. § 119 based on U.S. Provisional Pat. Application No. 63/052,988 filed on Jul. 17, 2020. The prior applications and all references cited therein are hereby incorporated by reference into the present disclosure in their entirety.

### FEDERALLY-SPONSORED RESEARCH AND DEVELOPMENT

The United States Government has ownership rights in this invention. Licensing inquiries may be directed to Office of Technology Transfer, US Naval Research Laboratory, Code 1004, Washington, DC 20375, USA; +1.202.767.7230; techtran@nrl.navy.mil, referencing Navy Case # 113402.

### TECHNICAL FIELD

The present invention relates to photodiodes, particularly to photodiodes that convert incident photons in the short-wave infrared (SWIR) spectral region to electric current.

### BACKGROUND

While there is not an official delineation of the SWIR spectral region, it is understood by skilled artisans in the field to span the range of approximately 1.1 - 3.0 µm. The operational range of this technology can be more precisely defined within the range of the telecommunications infrared bands (1260-1675 nm). See R. Ramaswami, “Optical fiber communication: from transmission to networking,” IEEE Comm. Mag. 2002, 40 (5) 138-147, DOI: 10.1109/MCOM.2002.1006983.

Colloidal nanocrystals are semiconducting particles, typically in the size regime of approximately 2-10 nm, formed through solution-phase reactions. Lead sulfide (PbS) nanocrystals (NCs) are an ideal material for low-cost infrared photodiodes due to their facile synthesis, tunable broadband light absorption, and compatibility with low-cost solution fabrication methods that allow direct deposition of the absorber layer onto the surface of silicon read-out integrated circuits (ROICs). This avoids the expensive and intricate hybridization process of the sensor material to the ROIC using indium bump-bonding that is required for epitaxially-grown semiconductor sensors, enabling sensor resolution to be limited only by the pixel pitch of the underlying ROIC architecture.

While SWIR PbS NC photodiode imagers have recently reached the commercial market, their device efficiencies lag behind those of epitaxial materials such as InGaAs and would benefit from improvements in surface modification to address the size-dependent surface properties of large, SWIR-absorbing PbS NCs.

PbS NC synthesis is facilitated by long-chain organic molecules (i.e., oleic acid, oleylamine, trioctylphosphine, etc.) that form a passivating ligand shell such as that illustrated by the block schematic in FIG. 1A around the NC surfaces. The term “pre-device processing ligands” can be used to refer to the organic surface ligands that maintain the shape and solubility of the NCs prior to film deposition and device processing. As illustrated by the schematic in FIG. 1B, these pre-device processing ligands are electrically insulating due to their relatively large size, which impedes charge carrier transport between nanocrystals. Formation of densely packed, conductive NC films is contingent upon exchange of the pre-device processing ligands with small molecules or ions that reduce particle separation and thus enable high charge carrier mobilities. Significant progress in PbS device performance has relied on advances in surface modification using halide-based ligand treatments developed for smaller-diameter (<3.5 nm), near-infrared (NIR) band gap NCs that are primarily terminated with lead-rich (111) surface facets. Such ligand exchange has demonstrated the highest device performance and greatest resistance to the deleterious effects of oxidation from exposure to ambient conditions.

However, PbS NCs that are suitable for use in SWIR photodiodes have a crystal surface facet termination that is different from that of PbS NCs suitable for use in NIR photodiodes.

As illustrated in FIG. 2A, small NIR-absorbing PbS nanocrystals have an octahedral shape terminated predominantly by polar (111) facets, while larger SWIR-absorbing PbS nanocrystals are cuboctahedral in shape, exhibiting both polar (111) and nonpolar (100) facets. As illustrated in FIG. 2B, these (111) and (100) facets exhibit significantly different surface chemistries that require passivation with different ligands and/or binding modes. The polar (111) facets are compatible with ionic ligands such as halides, while the relatively nonpolar (100) facets facilitate charge-neutral ligand passivation. Previous works with SWIR PbS devices utilize either nanocrystal passivation methods using small organic molecules (i.e., thiols and carboxylates) (see J. W. Lee, et al., “Inorganic UV-Visible-SWIR Broadband Photodetector Based on Monodisperse PbS Nanocrystals,” Small, 2016, 12, 1328-1333) or solution-phase ligand exchange methods (see J. Z. Fan, “Mixed Lead Halide Passivation of Quantum Dots,” Adv. Mater. 2019, 31, 1904304). The former suffers from reduced efficiency and stability to exposure from ambient conditions compared to exchange with halide ions. The latter entails a more complex fabrication protocol and necessitates single-step film deposition with specific solvent mixtures to maintain particle solubility, which can impose limitations on device fabrication, depending on the substrate surface chemistry and deposition method.

Therefore, the halide ligand exchange strategies used with small NIR band gap PbS NCs fail to sufficiently exchange the pre-device processing ligands on the (100) surface facets, present on larger SWIR band gap NCs, resulting in residual pre-device processing ligands and unpassivated surface sites that degrade device performance.

However, the more complex surface structure of larger, SWIR band gap PbS NCs requires passivation strategies to address both polar (111) and nonpolar (100) surface facets.

The majority of PbS NC device studies have employed synthetic methods utilizing lead oxide (PbO) precursors. Alternatively, PbS NCs can be synthesized using a large excess of PbCl₂ precursor following the procedures of Weidman et al. See M. C. Weidman, et al., “Monodisperse, Air-Stable PbS Nanocrystals via Precursor Stoichiometry Control,” ACS Nano 2014, 8 (6), 6363-6371. This synthetic route results in a native PbClₓ shell layer on the NCs, i.e., a shell layer that is inherent to the synthesis without need for additional processing steps. The improved surface passivation provided by the shell results in NCs with improved photoluminescence quantum yields and resistance to oxidation compared to their core-only counterparts derived via PbO precursors. The shell layer is approximately one monolayer thick as informed by studies that quantify the surface chemistry of these NCs. See S. Brittman, et al., “Effects of a Lead Chloride Shell on Lead Sulfide Quantum Dots,” J. Phys. Chem. Lett. 2019, 10, 1914-1918; and S.W. Winslow, “Quantification of a PbClₓ Shell on the Surface of PbS Nanocrystals,” ACS Materials Lett. 2019, 1, 209-216). These PbS/PbClₓ core/shell nanocrystals were previously overlooked for use in optoelectronic devices because the insulating properties PbClₓ were thought to inhibit the charge transport properties in NC films.

### SUMMARY

This summary is intended to introduce, in simplified form, a selection of concepts that are further described in the Detailed Description. This summary is not intended to identify key or essential features of the claimed subject matter, nor is it intended to be used as an aid in determining the scope of the claimed subject matter. Instead, it is merely presented as a brief overview of the subject matter described and claimed herein.

The present invention provides photodiodes that include PbS/PbClₓ core/shell nanocrystal absorber layer. Photodiodes having PbS/PbClₓ nanocrystals in the absorber layer in accordance with the present invention exhibit reduced current densities under reverse bias and greater infrared photoresponse compared to their core-only counterparts (PbS), thereby providing improved device performance as compared to photodiodes having absorber layers formed from PbS core nanocrystals alone.

### BRIEF DESCRIPTION OF THE DRAWINGS

FIGS. 1A and 1B are block schematics illustrating ligands and ligand exchange characteristics associated with PbS nanocrystals.

FIGS. 2A and 2 are block schematics illustrating the crystal structure (FIG. 2A) and crystal facet surface chemistry (FIG. 2B) of PbS nanocrystals that can be used in photodiodes for near-infrared (NIR) and short-wave infrared (SWIR), respectively.

FIGS. 3A and 3B are block schematics illustrating ligand exchanges on the nonpolar (100) and polar (111) facets of PbS core-only nanocrystals (FIG. 3A) and PbS/PbClₓ core/shell nanocrystals (FIG. 3B).

FIG. 4 is a block schematic illustrating the core/shell structure and ligand exchange activity of PbS/PbClₓ core/shell nanocrystals used in a SWIR photodiode in accordance with the present invention.

FIGS. 5A and 5B are block schematics illustrating exemplary structures of conventional photodiodes having absorber layers comprising PbS core-only nanocrystals (FIG. 5A) photodiodes having absorber layers comprising PbS/PbClₓ core/shell nanocrystals (FIG. 5B) in accordance with the present invention.

FIGS. 6A and 6B are plots illustrating the ligand exchange activity of conventional photodiodes having absorber layers comprising PbS core-only nanocrystals (FIG. 6A) photodiodes having absorber layers comprising PbS/PbClₓ core/shell nanocrystals (FIG. 6B) in accordance with the present invention.

FIGS. 7A and 7B are plots illustrating the current-voltage properties of conventional photodiodes having absorber layers comprising PbS core-only nanocrystals (FIG. 7A) photodiodes having absorber layers comprising PbS/PbClₓ core/shell nanocrystals (FIG. 7B) in accordance with the present invention.

FIG. 8 is a plot illustrating the external quantum efficiency of a conventional photodiode having absorber layers comprising PbS core-only nanocrystals and a photodiode having absorber layers comprising PbS/PbClₓ core/shell nanocrystals in accordance with the present invention.

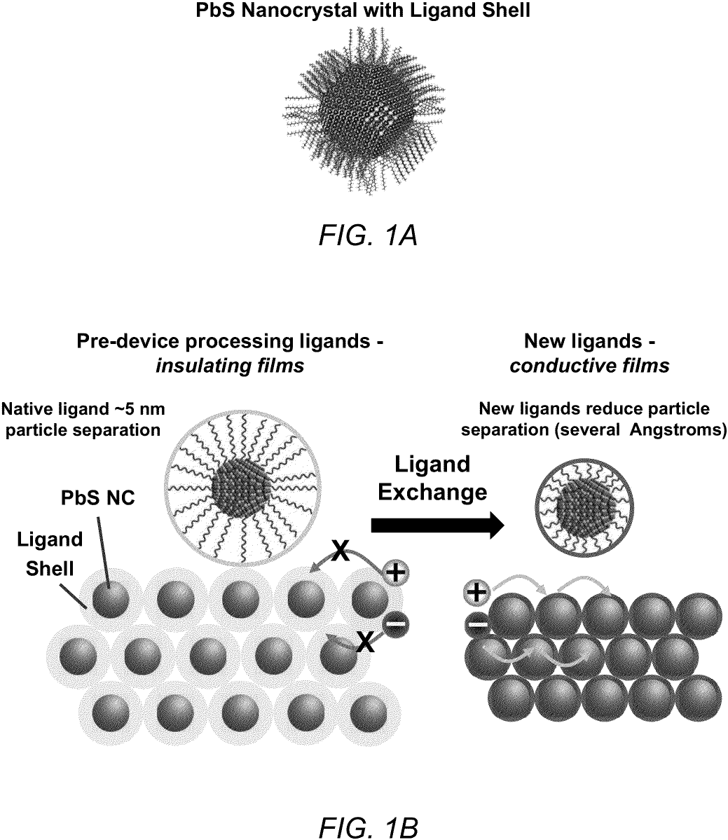

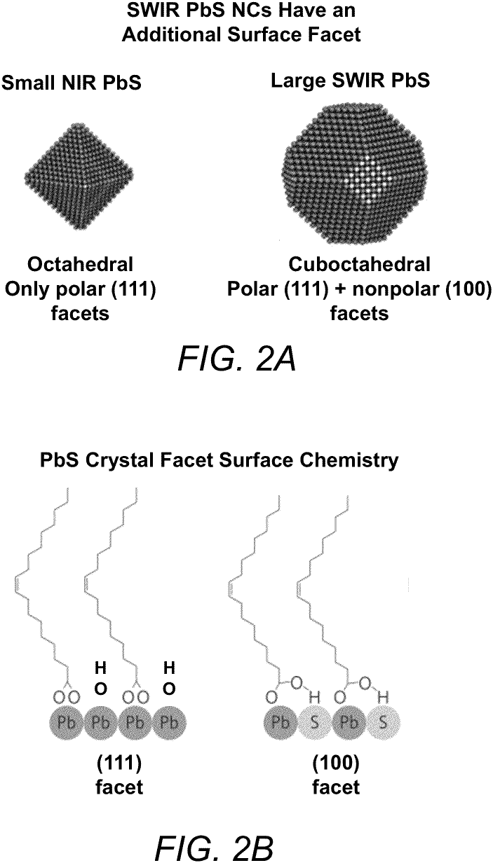

### DETAILED DESCRIPTION

The aspects and features of the present invention summarized above can be embodied in various forms. The following description shows, by way of illustration, combinations, and configurations in which the aspects and features can be put into practice. It is understood that the described aspects, features, and/or embodiments are merely examples, and that one skilled in the art may utilize other aspects, features, and/or embodiments or make structural and functional modifications without departing from the scope of the present disclosure.

The present invention provides enhanced infrared photodiodes having PbS/PbClₓ nanocrystal-based absorbers.

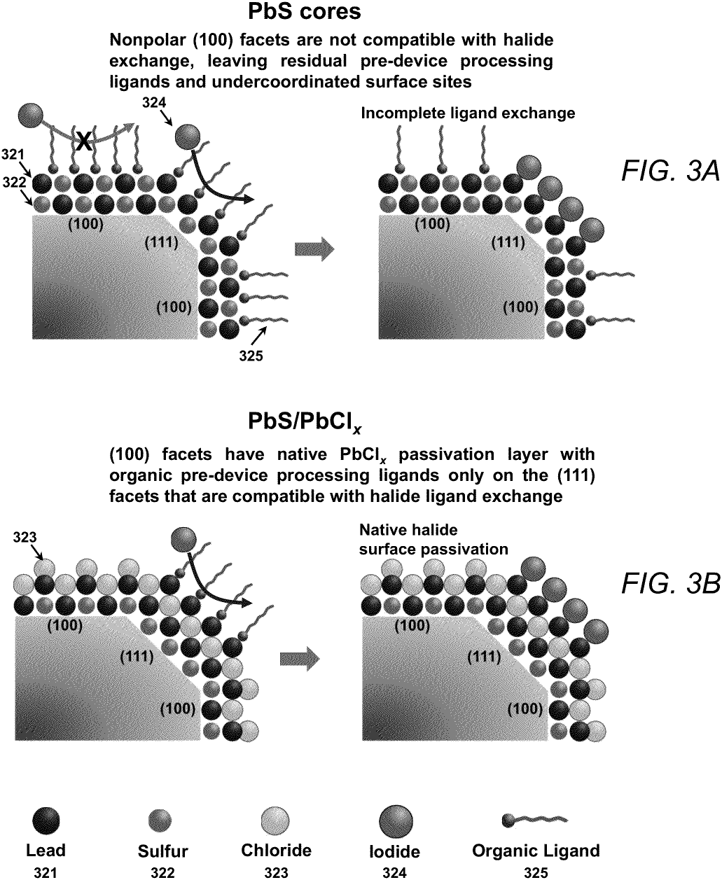

As noted above, solid-state halide ligand exchange of SWIR-absorbing PbS NC cores fails to address the nonpolar (100) surface facets, yielding incomplete removal of the pre-device processing ligands and unpassivated surface sites on the (100) surface facets of core-only films such that only the (111) facet is passivated, as depicted in FIG. 3A. The resulting surface defects degrade device performance by leading to high charge trap state densities, resulting in increased dark currents and defect-mediated tunneling associated with the observed diode-breakdown characteristics under reverse-bias conditions.

In contrast, the PbClₓ shell layer in the core/shell system provides native halide passivation to the (100) surfaces, while the (111) facets that serve as ligand binding sites are compatible with halide exchange such that the entire surface of the nanocrystal is passivated, as shown in FIG. 3B. This feature circumvents the need to separately address the (100) surfaces and permits the use of established layer-by-layer device fabrication and halide ligand exchange protocol with large-diameter (>5 nm) SWIR-absorbing PbS. The presence of the passivated (100) crystal plane surfaces and the ligand-exchanged (111) crystal plane surface are necessary for diode-rectification and increase the photodiode’s conversion of incident photons in the SWIR spectral range to electric current by mitigating losses due to nanocrystal surface defects.

Thus, as described in more detail below, by using PbS/PbClₓ core/shell nanocrystals as the absorber layer in accordance with the present invention, a photodiode having improved performance via reduced dark current densities, improved diode rectification, and increased photon-to-electron conversion efficiencies can be obtained.

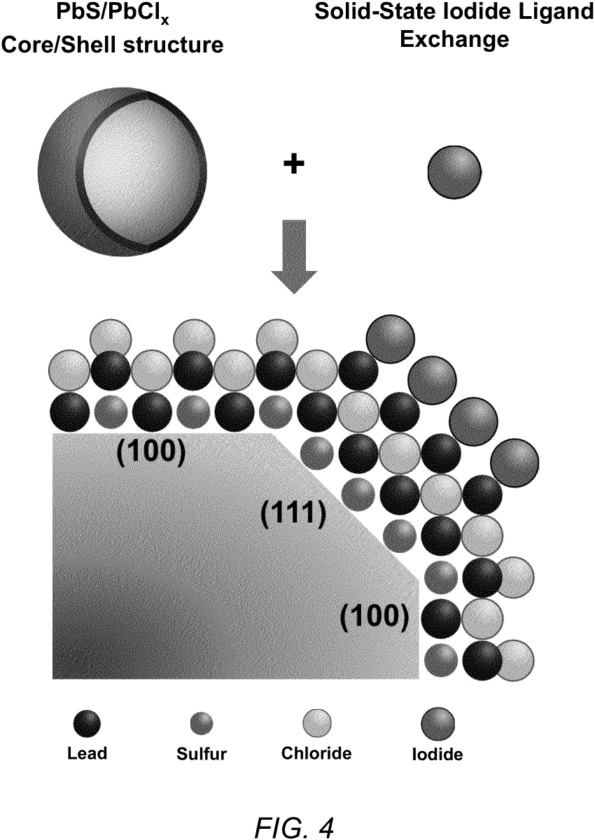

While the PbS/PbClₓ system and solid-state ligand exchange with halide salts are both prior art, this invention entails the application of these features to the fabrication of SWIR PbS photodiode devices (FIG. 4). This approach offers the processing and device efficiency advantages of solid-state halide ligand exchanges while maintaining compatibility with large-diameter SWIR PbS, that otherwise fails to translate to PbS core-only nanocrystals as demonstrated in FIG. 3A.

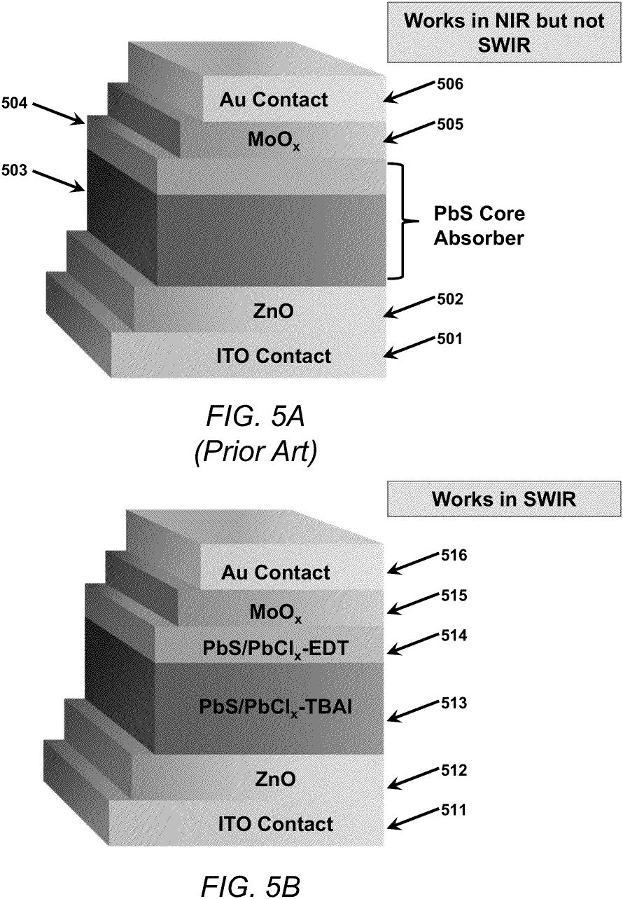

The block schematic in FIG. 5A illustrates aspects of an exemplary conventional photodiode that incorporates PbS nanocrystals in its absorber layer. As illustrated in FIG. 5A, such an exemplary conventional photodiode includes PbS nanocrystal-based absorber layers 503 and 504 sandwiched between ZnO electron-transport layer 502 and MoOₓ hole-transport layer 505, Au top contact layer 506 and indium-tin oxide (ITO)-coated glass bottom contact layer 501. However, as described above, although such a conventional photodiode operates well in the NIR, its performance in the SWIR suffers because of incompatibility of halide ligand exchange with the nonpolar (100) surfaces present on large-diameter PbS.

In contrast, the absorber layer of a photodiode in accordance with the present invention is based on PbS/PbClₓ core/shell nanocrystals which, as described above have native passivation of the (100) surface facets, enabling use of solid-state halide ligand exchange in large SWIR band gap PbS. Thus, in an exemplary embodiment such as that illustrated by the block schematic shown in FIG. 5B, a photodiode in accordance with the present invention includes a metal oxide or organic semiconductor-based electron-transport layer 512 and hole-transport layer 515, as well as Au top contact layer 516 and ITO-coated glass bottom contact layer 511, but substitutes the PbS core absorber layers of the conventional photodiode with PbS/PbClₓ core/shell nanocrystal-based absorber layers 513 and 514, where PbS/PbClₓ-TBAI absorber layer 513 was ligand-exchanged with tetrabutylammonium iodide (TBAI) and PbS/PbClₓ-EDT absorber layer 514 was treated with a 1,2-ethanedithiol (EDT) ligand solution. The thin (~40 nm) EDT-treated layer is used to create an energetic offset from the bulk of the TBAI-treated (iodide exchanged) film so as to facilitate hole transport and block electron-hole recombination at the interface, and is a common feature to improve the performance of PbS nanocrystal-based photodiodes.

Electron-transport layer 512 can comprise any suitable material such as ZnO, TiO₂, or fullerenes, while hole-transport layer 515 can comprise a metal oxide such as MoOₓ, VOₓ, or NiO; an organic compound such as Spiro-OMeTAD (2,2′,7,7′-Tetrakis[N,N-di(4-methoxyphenyl)amino]-9,9′-spirobifluorene) or polytriarylamine (Poly[bis(4-phenyl) (2,4,6-trimethylphenyl)amine); or any other suitable material, and all such cases are within the scope of the present invention.

In some cases, the PbS/PbClₓ core/shell nanocrystals in the absorber layer can be fabricated as described below, but one skilled in the art will recognize that PbS/PbClₓ core/shell nanocrystals from any suitable source can be used, and photodiodes having all such PbS/PbClₓ core/shell nanocrystal-based absorber layers are deemed to be within the scope of the present invention.

### EXAMPLE

Exemplary photodiodes having conventional PbS core nanocrystal-based absorbers and having PbS/PbClₓ core/shell nanocrystal-based absorbers in accordance with the present invention were fabricated and their performance was evaluated. As described below, the photodiodes having PbS/PbClₓ core/shell nanocrystal-based absorbers in accordance with the present invention exhibited greater external quantum efficiencies (EQE) in the SWIR region, improved diode-rectification characteristics, and reduced dark current densities under low reverse bias conditions as compared to the photodiodes having conventional PbS core nanocrystal-based absorbers.

### PbS Nanocrystal-Based Device Fabrication

Conventional photodiodes having the layer structure illustrated in FIG. 5A were spin-cast in ambient conditions using a layer-by-layer approach based on previous literature reports. See D. Placencia, et al., “Energy Level Alignment of Molybdenum Oxide on Colloidal Lead Sulfide (PbS) Thin Films for Optoelectronic Devices,” ACS Applied Materials & Interfaces 2018, 10 (30), 24981-24986; and C. H. Chuang, et al., “Improved performance and stability in quantum dot solar cells through band alignment engineering,” Nat. Mater. 2014, 13 (8), 796-801.

The substrates were ITO-coated glass (Delta Technologies Ltd.) having a thickness of 150 nm and a sheet resistance of ~10 ohms/cm². The 1 in. × 1 in. substrates were patterned with using a positive resist (Rohm and Haas, S1813), processed with the necessary exposure, development, and heating steps. The exposed ITO was etched by submersing the substrates in TE-100 tin oxide etchant on a hotplate set to 120° C. The resist was removed by rinsing with acetone. The ZnO layer was deposited by spin-casting two layers of the ZnO nanocrystal solution at 2000 rpm and annealing at 200° C. for 10 minutes.

The PbS nanocrystals in these conventional devices were dispersed in anhydrous n-heptane at a concentration of 20 mg/mL and filtered to remove particulates (PTFE, 0.45 µm pore size). Each layer was deposited by covering the film surface with a PbS solution and spin-casting at 2000 rpm. The bulk of the film was ligand exchanged with tetrabutylammonium iodide (TBAI, 10 mg/mL in methanol), rinsed twice with methanol and spun dry. The final two layers (~40 nm) were treated with 1,2-ethanedithiol (EDT, 0.05% v/v in acetonitrile) and rinsed twice with acetonitrile. The PbS films were air annealed at 90° C. for 3 min. and transferred to a nitrogen glove box with built-in thermal evaporator, in which 15 nm MoOₓ and 100 nm gold films were successively deposited.

### PbS/PbClₓ Core/Shell Nanocrystal-Based Device Fabrication

The devices having PbS/PbClₓ core/shell nanocrystal-based absorbers in accordance with the present invention were similarly fabricated, except for the fabrication of the PbS/PbClₓ core/shell nanocrystal layers, as now described.

In the exemplary devices whose performance was examined, the PbS/PbClₓ nanocrystals were synthesized using standard air-free Schlenk techniques following a modified version of the procedures from Weidman et al. See M. C. Weidman, et al., “Monodisperse, Air-Stable PbS Nanocrystals via Precursor Stoichiometry Control,” ACS Nano 2014, 8 (6), 6363-6371. The sulfur precursor was prepared in a Schlenk flask, to which 132 mg sulfur powder and 5.5 mL dry oleylamine were added, and briefly heated to 120° C. under argon atmosphere with vigorous stirring until the sulfur was completely dissolved. The flask was then removed from the heating mantle and slowly cooled to room temperature, while maintaining the inert atmosphere. PbCl₂ (12.5 g) and oleylamine (75 mL, 70% technical grade) were mixed in a 250 mL 3-neck flask with continuous stirring, and degassed at 110° C. for 30 min. The flask was then transitioned to argon atmosphere and the temperature increased to 120° C. The sulfur precursor (5 mL) was rapidly injected into the flask, and the mixture was left to stir at 120° C. for 60 min., after which the reaction was quenched via rapid cooling to approximately 75° C., then slow cooling to room temperature.

Cleaning steps were performed in a nitrogen glove box with anhydrous solvents. First, 20 mL hexane was added to the flask and mixed, and the product was split between four centrifuge tubes. Excess PbCl₂ was removed from the suspension via centrifugation, and the nanocrystal phase (suspended in hexane) was decanted into four clean tubes. Precipitation was performed via the addition of 12 mL ethanol per tube and centrifuging. An oleic acid ligand exchange was performed by dispersing the particles in 30 mL hexane and adding 2 mL oleic acid. After mixing well and letting the mixture stand for 5 min., the particles were precipitated with ethanol and collected via centrifugation, and this procedure was repeated once. The produced was subsequently cleaned twice by dispersing in 10 mL toluene and precipitation with 20 mL acetonitrile, followed by centrifugation. The clean nanocrystal product was transferred to a vial and stored dry in a nitrogen glove box until used.

The thus-prepared PbS/PbClₓ core/shell nanocrystals were incorporated into the absorber layers of the photodiode, as described in the above device fabrication protocol, to result in a photodiode such as that illustrated in FIG. 5B.

Devices used for the current density-voltage (J-V) measurements were patterned with device areas of 0.019 cm², while those used for quantum efficiency measurements had active areas of 0.125 cm². For testing, the devices were contained in a hermetically sealed chamber with feedthroughs for the electrical contacts. Data for the J-V measurements was acquired using a Keithley 2400 source meter under illumination from a 1000 W solar simulator (Newport Corporation) using an air:mass (AM) 1.5G filter with the intensity calibrated to 100 mW/cm² using a standardized silicon reference cell. For the infrared illuminated characterization, the AM 1.5G illumination was filtered using a c-silicon wafer as a 1.1 µm long-pass filter. Data for the external quantum efficiency measurements was collected on a home-built setup using illumination from a 150 W Xenon DC arc lamp (Newport Corp) and a Newport Cornerstone 130 monochromator, modulated with a SR 540 chopper system at 250 Hz. Data was acquired with a SR560 low noise preamplifier and a SR810 lock-in amplifier. The incident light intensity was determined using silicon (818-SL/DB) and germanium (818-IR/DB) calibrated photodiodes (Newport).

### Ligand Exchange

Thickness-dependent oxygen and carbon XPS analysis was performed on the PbS and PbS/PbClₓ core/shell nanocrystal films incorporated into the photodiode devices as described above, where the nanocrystals were spin-cast onto gold-coated glass substrates with a ZnO nanocrystal layer, followed by iodide ligand exchange.

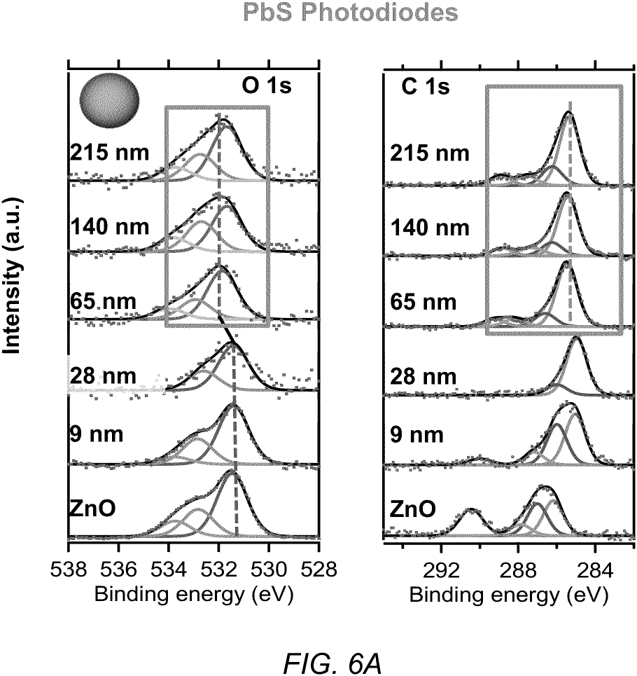

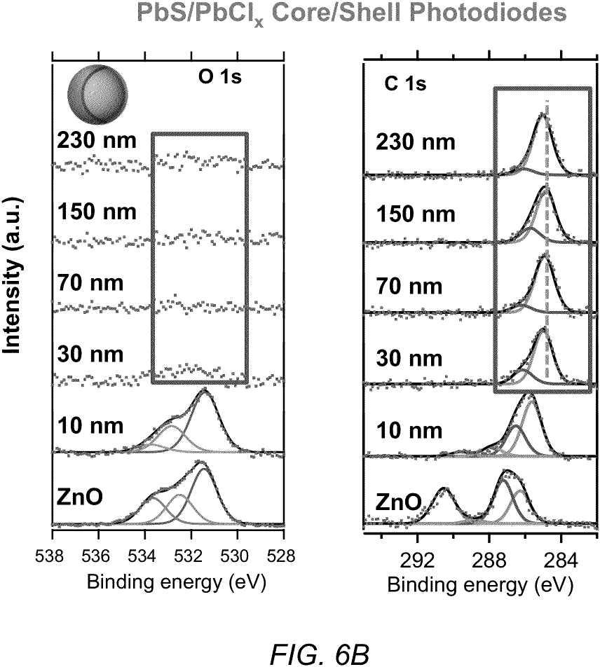

FIGS. 6A and 6B show the results of this XPS analysis of these PbS and PbS/PbClₓ core/shell nanocrystal films and show evidence of incomplete ligand exchange in the PbS core-only nanocrystal films, while the PbS/PbClₓ core/shell nanocrystal films show near-complete removal of the organic pre-device processing ligands.

Thus, as can be seen in FIG. 6A, the XPS peaks for the PbS core-only nanocrystal films exhibit shifts and additional peaks that indicate the presence of multiple carbon species distinct from normal carbon surface contamination. The organic pre-device processing ligands have oxygen present in carboxylate functional groups, and the distinct oxygen and carbon species indicated by the XPS peaks shown in the plots in FIG. 6A indicate incomplete removal of the pre-device processing ligands during the ligand exchange.

In contrast, as can be seen in FIG. 6B, the XPS peaks for the PbS/PbClₓ core/shell nanocrystal films exhibit no oxygen peaks, which indicate removal of the pre-device processing ligands for those nanocrystals. While present, the carbon peaks for the PbS/PbClₓ core/shell nanocrystal films are characteristic of surface contamination and exhibit consistent features with no shift as a function of film thickness (compared to the shift in carbon peak shown in FIG. 6A) and do not indicate an incomplete removal of pre-device processing ligands.

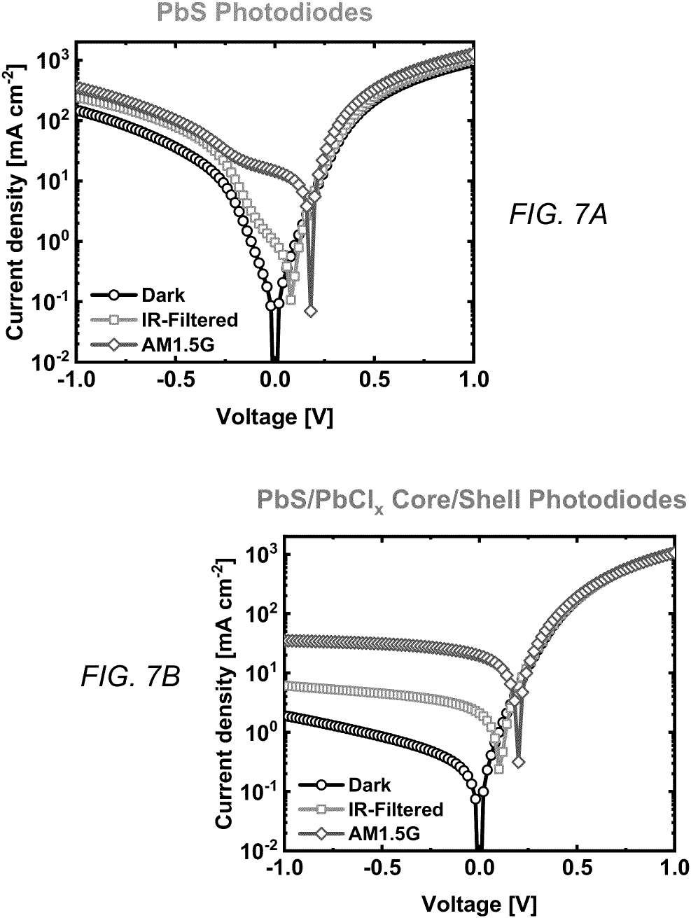

The plots in FIGS. 7A and 7B illustrate the improved photovoltaic performance of a photodiode having a PbS/PbClₓ core/shell nanocrystal-based absorber layer as compared to the performance of a photodiode having a conventional PbS core-only nanocrystal absorber layer and further illustrates that the incomplete removal of pre-device processing surface ligands in PbS nanocrystals reduces device performance as compared to PbS/PbClₓ core/shell nanocrystals, which have more complete ligand exchange.

As can be seen from a comparison of the plots in FIGS. 7A and 7B, the PbS core-only photodiodes suffer from highly non-ideal current-voltage characteristics, with significant shunting effects (diode-breakdown) as compared to PbS/PbClₓ core/shell nanocrystal photodiodes. As seen in FIG. 7B, the PbS/PbClₓ core/shell nanocrystal photodiodes, in accordance with the present invention, show more ideal J-V curves with improved diode-rectification and lower dark current densities under reverse bias conditions. In addition, the lower short-circuit current density (J_{sc}) under IR-filtered AM 1.5G illumination indicates that such photodiodes exhibit reduced photon-to-electron conversion efficiency, compared to the PbS/PbClₓ system, that exhibit higher J_{sc} values under both broadband and IR-Filtered illumination.

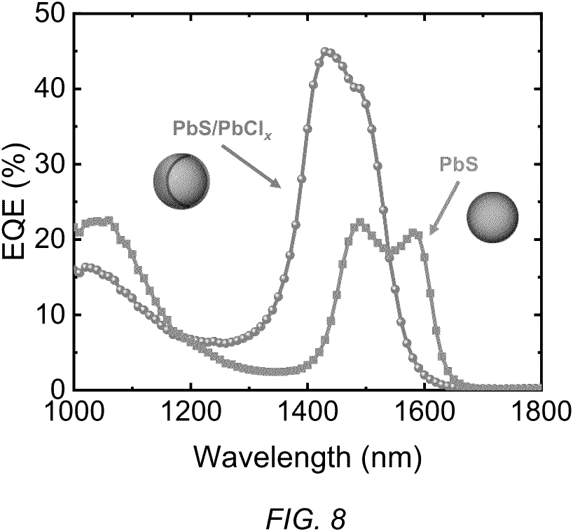

The plot in FIG. 8 illustrates the results of an evaluation of the external quantum efficiencies (EQE) of conventional PbS core-only nanocrystal-based photodiodes versus the PbS/PbClₓ core/shell nanocrystal photodiodes in accordance with the present invention. As shown in FIG. 8, the EQE of the PbS core-only device remains mostly under 20%, whereas the EQE of the PbS/PbClₓ core/shell nanocrystal photodiodes in accordance with the present invention is considerably higher, up to 40% higher in the SWIR region.

In addition, as shown in Table I below, the core/shell-based devices exhibit greater EQE response in the SWIR region, and dark current values under low reverse bias conditions that are approximately an order of magnitude lower compared to their core-only counterparts. The higher SWIR efficiencies observed with the thicker active layer devices is in part due to an intrinsic optical cavity effect (Fabry Perot resonance peaks) due to the device geometry.

TABLE I

Core vs. Core/Shell Performance @ 300 K

| PbS Type | Thickness (nm) | λₘₐₓ (nm) | EQE (%) | \|J_{dark}\|@ -300mV (mA/cm²) |
|---|---|---|---|---|
| Core | 260 | 1270 | 23 | 1.8 |
| Core/Shell | 260 | 1250 | 41 | 0.2 |
| Core | 340 | 1490 | 22 | 2.1 |
| Core/Shell | 340 | 1430 | 45 | 0.21 |

### Advantages and New Features

The core/shell NC system allows device fabrication using halide ion exchange with established layer-by-layer fabrication methods and device architectures with large-diameter, SWIR absorbing PbS nanocrystals. This is an inherent advantage, since it is a material that can be dropped into current processes that make use of this technology.

In summary, we have demonstrated the use of PbS/PbClₓ core/shell nanocrystals in SWIR photodiodes, with sensitivity ranging from the UV region to 1.5 µm. Devices using core/shell nanocrystals exhibit improved optical response as well as significantly reduced dark current densities in reverse bias compared to conventional PbS cores, allowing greater overall signal-to-noise detection. Investigation of the PbS/ZnO interface using thickness-dependent XPS/UPS measurements indicate a greater shift of the local vacuum level in the case of the PbS/PbClₓ system, resulting most likely from a combination of band bending and interface dipoles. While the extent of each effect cannot be precisely quantified, our measurements suggest that stronger interface dipole formation likely improves electron collection and mitigates losses due to carrier recombination, resulting in the observed improvements in device measurements. Our findings highlight the importance of nanocrystal surface chemistry in governing device electronic properties, and will help inform the optimization of PbS infrared photodiodes in future studies.

Although particular embodiments, aspects, and features have been described and illustrated, one skilled in the art would readily appreciate that the invention described herein is not limited to only those embodiments, aspects, and features but also contemplates any and all modifications and alternative embodiments that are within the spirit and scope of the underlying invention described and claimed herein. The present application contemplates any and all modifications within the spirit and scope of the underlying invention described and claimed herein, and all such modifications and alternative embodiments are deemed to be within the scope and spirit of the present disclosure.

What is claimed is:

1. A short-wave infrared (SWIR) photodiode, comprising:
at least one absorber layer comprising a plurality of solution-processed PbS/PbClₓ core/shell nanocrystals;
wherein the PbS/PbClₓ core/shell nanocrystals exhibit native PbClₓ passivation on the (100) crystal plane surfaces of the PbS/PbClₓ core/shell nanocrystals and further exhibit an exchange of pre-device processing ligands with halide ligands on the (111) crystal plane surface of the PbS/PbClₓ core/shell nanocrystals;
wherein a presence of the passivated (100) crystal plane surfaces and the ligand-exchanged (111) crystal plane surface are necessary for diode-rectification and increase the photodiode’s conversion of incident photons in the SWIR spectral range to electric current by mitigating losses due to nanocrystal surface defects.

2. The photodiode according to claim 1, further comprising a metal oxide or organic semiconductor-based electron-transport layer situated on a bottom surface of the absorber layer and a metal oxide hole-transport layer situated on an upper surface of the absorber layer.

3. The photodiode according to claim 2, wherein the electron-transport layer comprises ZnO, TiO₂, or fullerenes.

4. The photodiode according to claim 2, wherein the hole-transport layer comprises MoOₓ, VOₓ, or NiO.

5. The photodiode according to claim 2, wherein the hole-transport layer comprises Spiro-OMeTAD or polytriarylamine.

6. The photodiode according to claim 1, wherein the absorber layer comprises a PbS/PbClₓ-TBAI absorber layer, wherein at least some of the pre-device processing ligands are ligand-exchanged with tetrabutylammonium iodide (TBAI).

7. The photodiode according to claim 1, wherein the absorber layer comprises a PbS/PbClₓ-EDT absorber layer, wherein at least some of the pre-device processing ligands are treated with a 1,2-ethanedithiol (EDT) ligand solution.
